(19) United States
(12) Patent Application Publication
(10) Pub. No.: US 2013/0220399 A1
(43) Pub. Date: Aug. 29, 2013

(54) HYBRID WEDGE SHAPED/MICROSTRUCTURED LIGHT COLLECTOR

(71) Applicants: Russell Wayne Gruhlke, Milpitas, CA (US); Sijin Han, Milpitas, CA (US); Fan Yang, Sunnyvale, CA (US)

(72) Inventors: Russell Wayne Gruhlke, Milpitas, CA (US); Sijin Han, Milpitas, CA (US); Fan Yang, Sunnyvale, CA (US)

(73) Assignee: QUALCOMM MEMS Technologies, Inc., San Diego, CA (US)

(21) Appl. No.: 13/403,786

(22) Filed: Feb. 23, 2012

(51) Int. Cl. H01L 31/04; H01L 31/18

(52) U.S. Cl. 136/246; 438/65; 257/E31.127

(57) ABSTRACT

This disclosure provides systems, methods and apparatus including a hybrid wedge shaped/microstructured light collector that is optically coupled to one or more photovoltaic cells. In one aspect, the hybrid wedge shaped/microstructured light collector includes a wedge shaped light guide having an inclined light receiving surface that can collect light incident at angles in the range from about 60 degrees to about 90 degrees with respect to a normal to the inclined light receiving surface. Additionally, the hybrid wedge shaped/microstructured light collector includes a microstructured light collector that can collect light incident at angles in the range from about 0 degrees to about 60 degrees with respect to a normal to the inclined light receiving surface.

### TECHNICAL FIELD

This disclosure relates to the field of light collectors and concentrators and more particularly to using micro-structured light guides to collect and concentrate solar radiation.

### DESCRIPTION OF THE RELATED TECHNOLOGY

Solar energy is a renewable source of energy that can be converted into other forms of energy such as heat and electricity. Some drawbacks in using solar energy as a reliable source of renewable energy are low efficiency in collecting solar energy, in converting light energy to heat or electricity and the variation in the solar energy depending on the time of the day and the month of the year.

A photovoltaic (PV) cell can be used to convert solar energy to electrical energy. Systems using PV cells can have conversion efficiencies between 10-20%. PV cells can be made very thin and are not big and bulky as other devices that use solar energy. For example, PV cells can range in width and length from a few millimeters to 10's of centimeters. Although, the electrical output from an individual PV cell may range from a few milliwatts to a few watts, due to their compact size, several PV cells may be connected electrically and packaged to produce a sufficient amount of electricity. For example, a solar panel including a plurality of PV cells, can be used to produce sufficient amount of electricity to satisfy the power needs of a home.

Solar concentrators can be used to collect and focus solar energy to achieve higher conversion efficiency in PV cells. For example, parabolic mirrors can be used to collect and focus light on PV cells. Other types of lenses and mirrors can also be used to collect and focus light on PV cells. These devices can increase the light collection efficiency. But such systems tend to be bulky and heavy because the lenses and mirrors that are required to efficiently collect and focus sunlight have to be large.

Accordingly, for many applications such as, for example, providing electricity to residential and commercial properties, charging automobile batteries and other navigation instruments, it is desirable that the light collectors and/or concentrators are compact in size.

### SUMMARY

The systems, methods and devices of the disclosure each have several innovative aspects, no single one of which is solely responsible for the desirable attributes disclosed herein.

One innovative aspect of the subject matter described in this disclosure can be implemented in an apparatus, comprising a wedge-shaped first light guide configured to guide light incident on a light receiving surface of the first light guide within a first angular range. The first light guide includes a first side, a second side and a third side which includes the light receiving surface. The first and third side subtends a first apex angle and a portion of the third side defines a surface plane having a normal direction P. The second side is disposed opposite the first apex angle and the second side is shorter in length than the first side and the third side. The apparatus further includes a first light collector positioned adjacent to the first side of the first light guide to receive light that exits the first side of the first light guide. The first light collector includes microlenses disposed on a first side of the first light collector proximate to the first side of the first light guide. Each of the microlenses has an optical axis. The microlenses are configured to propagate incident light received at a second angular range different from the first angular range into the first light collector. The apparatus further includes turning features disposed on a second side of the first light collector opposite the microlenses and angled to reflect light received through the microlenses towards an illumination surface of the first light collector that is disposed proximate to the second side of the light guide. At least one photovoltaic cell is disposed adjacent to the second side of the first light guide and to the illumination surface. In various implementations, the turning features can include prismatic features.

In various implementations, the apparatus described above can further include a wedge-shaped second light guide and a second light collector. The second light collector can be disposed adjacent to the first light collector such that a side having turning features of the second light collector is disposed proximate to the side of the first light collector having turning features. The wedge-shaped second light guide has a first side, a second side, and a third side including a light receiving surface. The first and third side of the second light guide subtends a second apex angle. The second side is disposed opposite the second apex angle and the second side is shorter in length than the first side. The third side is disposed such that the first side of the second light guide is adjacent to the second light collector on a side of the second light collector opposite the first light collector. In various implementations, the first and/or the second apex angle can between about 3 and 30 degrees. Various implementations of the apparatus described above can be configured as a portion of a facade of a building.

In various implementations of the apparatus described above, the first angular range can be between about 60 degrees and 90 degrees from the direction of the surface normal P. In various implementations, the second angular range can be between about 0 degrees and 60 degrees from the direction of surface normal P. In various implementations, the alignment of each of the turning features can be offset with respect to the optical axis of each of the microlenses by a distance which is between approximately 1 mm and approximately 1 cm. In various implementations, light incident on the first light collector can be focused by the microlenses onto the array of turning features. In various implementations, the turning features can be configured to redirect the light towards the at least one photovoltaic cell.

In various implementations of the apparatus described above, the first light collector can include a substrate having a first surface and a second surface rearward of the first surface. The microlenses can be disposed on the first surface of the substrate. The first light collector can further include a light guide layer having a forward and a rearward surface. In various implementations, the forward surface of the light guide can be disposed proximal to the second surface of the substrate and be configured to receive incident light. In various implementations, the turning features can be disposed on the rearward surface of the light guide layer. In various implementations of the apparatus described above, a layer of material can be disposed between the light guide layer and the substrate. The layer of material can have a refractive index characteristic lower than the refractive index of the light guide and/or the refractive index of the substrate.

Various implementations of the apparatus described above can be attached to a window of a building. Various implementations of the apparatus described above can be configured as a window of a building and/or as a skylight of a building.

Another innovative aspect of the subject matter described in this disclosure can be implemented in an apparatus comprising a wedge-shaped first means for guiding light that is incident on a light receiving surface of the first light guiding means within a first angular range towards at least one photovoltaic cell that is disposed adjacent to a surface of the first light guiding means. The apparatus further includes a second means for guiding light, received at a second angular range that is different from the first angular range, towards at least one photovoltaic cell that is disposed adjacent to a surface of the second light guiding means. The second light guiding means is positioned adjacent to a first side of the first light guiding means to receive light that exits the first side of the first light guiding means. In various implementations, the first and/or the second light guiding means can includes a light guide.

In various implementations of the apparatus described above, the first light guiding means can include a first light guide that includes a first side, a second side, and a third side. The third side can include a light receiving surface. In various implementations, the first and third side can subtend a first apex angle of between approximately 3 and approximately 30 degrees. A portion of the third side can define a surface plane having a normal direction P. In various implementations, the second side can be disposed opposite the first apex angle and the second side can be shorter in length than the first side and/or the third side.

In various implementations of the apparatus described above, the second light guiding means can include microlenses that are disposed on a side of the second light guiding means that is proximate to a first side of the first light guiding means. In various implementations of the apparatus described above, the second light guiding means can further include turning features that are disposed on a side of the second light guiding means that is opposite the first side including the microlenses. In various implementations, the light turning features can have at least one angled surface that is configured to reflect light passing through the microlenses towards the at least one photovoltaic cell.

Various implementations of the apparatus described above can further include a wedge-shaped third means for guiding light that is incident on a light receiving surface of the third light guiding means within a first angular range, towards at least one photovoltaic cell disposed adjacent to a surface of the third light guiding means. Various implementations can further include a fourth means for guiding light that is received at a second angular range different from the first angular range, towards at least one photovoltaic cell disposed adjacent to a surface of the fourth light guiding means. In various implementations, the fourth light guiding means can be positioned adjacent to a first side of the third light guiding means to receive light that exits the first side of the third light guiding means. In various implementations, the fourth light guiding means can be disposed adjacent to the second light guiding means. In various implementations, the at least one photovoltaic cell that is disposed adjacent to a surface of the first, second, third or fourth light guiding means can be a part of a single photovoltaic cell or a panel including multiple photovoltaic cells.

Another innovative aspect of the subject matter described in this disclosure can be implemented in a method of manufacturing an apparatus. The method comprises providing a first wedge shaped light guide that is configured to collect and guide light in a first angular range. The first wedge shaped light guide includes a first side, a second side and a third side. The third side includes the light receiving surface. The first and the third side subtend a first apex angle and the second side is disposed opposite the first apex angle. The second side is shorter in length than the first side and the third side. The method further includes disposing a first light collector rearward of the first wedge shaped light guide. The first light collector can include an array of microlenses and an array of turning features. The first light collector can be configured to collect light that exits the first wedge shaped light guide and is incident on the first light collector in a second angular range that is different from the first angular range. The method further includes disposing at least one photovoltaic cell adjacent the second side of the first wedge shaped light guide, the photovoltaic cell is configured to receive light incident through the inclined surface of the first wedge shaped light guide and trapped by total internal reflection within the first wedge shaped light guide and the first light collector.

In various implementations, the array of microlenses and/or the array of turning features can be formed by a process such as, for example, embossing, etching, imprinting and/or lithography. In various implementations, the array of microlenses can be provided on a first side of the first light collector that is proximal to the wedge shaped light guide. In various implementations, the array of microlenses can be provided on a film that is disposed on the first side of the first light collector. In various implementations, the array of turning features can be provided on a second side of the first light collector that is opposite the first side. In various implementations, the array of turning features can be provided on a film that is disposed on the second side of the first light collector.

Another innovative aspect of the subject matter described in this disclosure can be implemented in a method of directing light towards a photovoltaic cell. The method comprises receiving light incident in a first angular range on an inclined surface of a wedge shaped light guide. The method further includes guiding a portion of the received light towards at least one photovoltaic cell disposed at one end of the wedge shaped light guide. The method further includes receiving at least a portion of light that exits the wedge shaped light guide on a light collector disposed along a surface of the wedge shaped light guide. In various implementations, the light collector is configured to collect and guide light by focusing light incident on the light collector onto an array of turning features using an array of microlenses that are disposed on a first side of the light collector that is positioned proximal to the wedge shaped light guide. In various implementations, the array of turning features can be disposed on a second side of the light collector opposite the first side. In various implementations the focused light is redirected using the array of turning features towards the at least one photovoltaic cell. In various implementations, the first angular range can be between about 60 degrees and about 90 degrees with respect to a normal to the inclined surface. In various implementations, the light collector can be configured to collect and guide light that is incident in a second angular range between about 0 degrees and about 60 degrees with respect to a normal to the inclined surface.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

Example implementations disclosed herein are illustrated in the accompanying schematic drawings, which are for illustrative purposes only.

FIGS. 1A and 1B illustrate an implementation of a wedge shaped light guide that can be used to collect light.

FIGS. 2A-2C illustrate implementations of a light collector, having microstructures, that can be used to collect light.

FIGS. 3A-3C illustrate a cross-sectional view of an example of a hybrid light collecting structure including a wedge shaped light guide and a microstructured light collector.

FIG. 4 illustrates a cross-sectional side view of an implementation of a hybrid light collecting structure that can be disposed on windows of buildings.

FIG. 5 illustrates an example of a hybrid light collecting structure coupled to PV cells that can be integrated with a building.

FIG. 6 illustrates an example of a hybrid light collecting structure coupled to PV cells disposed on an automobile.

FIG. 7 illustrates an example of a hybrid light collecting structure coupled to PV cells that is attached to the housing (for example external casing) of a laptop computer.

FIG. 8 illustrates an example of a hybrid light collecting structure coupled to PV cells that is attached to an article of clothing.

FIG. 9 illustrates an example of a hybrid light collecting structure coupled to PV cells disposed on a shoe.

FIG. 10 illustrates an example of a hybrid light collecting structure coupled to PV cells that is flexible to be rolled.

FIG. 11 is a flow chart illustrating an example of a method of manufacturing an implementation of a hybrid light collecting structure.

FIGS. 12A and 12B are flow charts illustrating an example of a method of directing light towards a PV cell using an implementation of a hybrid light collecting structure.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. As will be apparent from the following description, the innovative aspects may be implemented in any device that is configured to collect, trap and concentrate radiation from a source. More particularly, it is contemplated that the innovative aspects may be implemented in or associated with a variety of applications such as providing power to residential and commercial structures and properties, providing power to electronic devices such as laptops, personal digital assistants (PDA's), wrist watches, calculators, cell phones, camcorders, still and video cameras, MP3 players, etc. In addition the implementations described herein can be used in wearable power generating clothing, shoes and accessories. Some of the implementations described herein can be used to charge automobile batteries or navigational instruments and to pump water. The implementations described herein can also find use in aerospace and satellite applications. Other uses are also possible.

As discussed more fully below, in various implementations described herein, a solar collector and/or concentrator is coupled to a PV cell. For clarity of description, “solar collector” or simply “collector” can be used to refer to either or both a solar collector and a solar concentrator, unless otherwise indicated. The solar collector can include a first wedge shaped light guide that can collect and guide light, which is incident on an exposed surface, in a first range of angles to a PV cell. Light that is incident on an exposed surface of the collector in a second range of angles and that is not guided by the first wedge shaped light guide is collected by a second light collector and guided within the second light collector toward the PV cell. The second light collector includes a plurality of microlenses on a first side of the second light collector to collect and direct incident light in the second range of angles to a second side of the second light collector. A plurality of turning features are disposed on the second side of the second light collector to turn the light collected by the microlenses such that light incident in the second range of angles is guided within the second light collector towards the PV cell. The wedge shaped light guide and/or the second light collector may be formed as a plate, sheet or film. The wedge shaped light guide and/or the second light collector may be fabricated from a rigid or a semi-rigid material. The wedge shaped light guide and/or the second light collector may be formed of a flexible material. In some implementations, the solar collector can include a thin film including reflective, diffractive or scattering features. The reflective, diffractive or scattering features included in the thin film can reflect, diffract or scatter the incident light such that it is guided in the wedge-shaped light guide and/or the second light collector towards the PV cell. In various implementations, the microlenses and/or the plurality of turning features can be included in thin films which may be adhered or laminated to the first and second sides of the second light collector. The plurality of turning features disposed on the second side of the second light collector can include turning features. The turning features can include prismatic features such as formed by grooves that are arranged in a linear fashion. In some implementations, the prismatic features can have non-linear extent. For example, the prismatic features can be arranged along curves.

Particular implementations of the subject matter described in this disclosure can be implemented to realize one or more of the following potential advantages. A solar collector and/or concentrator, such as, for example, the implementations described herein can be used to collect, concentrate and direct ambient light to PV cells in opto-electronic devices that convert light energy into electricity and/or heat with increased efficiency and lower cost. For example, the implementations described herein can be integrated in architectural structures such as, for example, windows, roof, skylights, or facades to generate photovoltaic power. Solar collectors and/or concentrators, such as for example, the implementations described herein allow for efficiently collecting solar light incident at various incident angles during the day. Additionally, the implementations of the solar concentrators and/or collectors described herein can efficiently collect light over a wide range of incident angles. For example, the implementations of the solar concentrators and/or collectors described herein can efficiently collect light incident along a normal to the light receiving surface of the solar concentrators and/or collectors as well as light incident at non-normal angles.

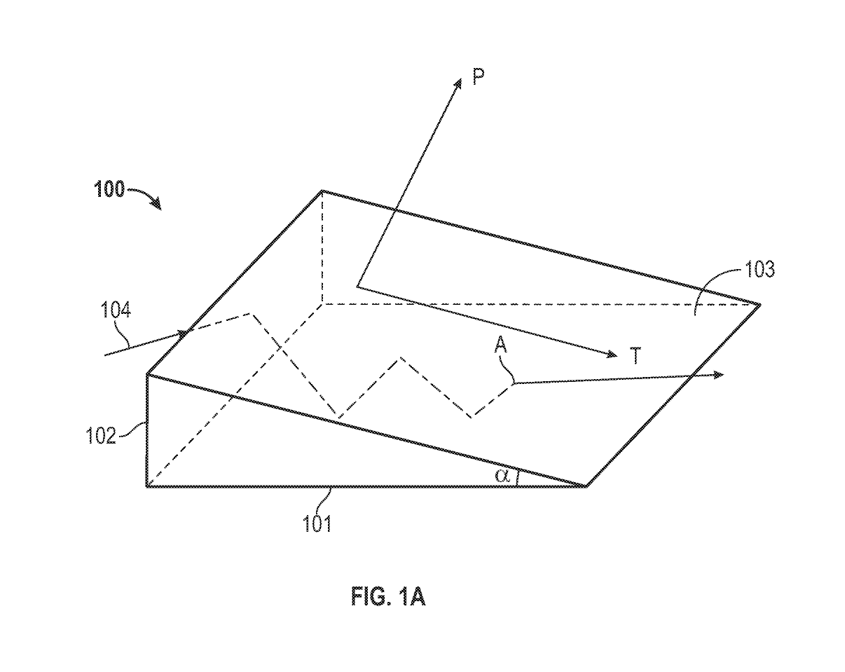

FIGS. 1A and 1B illustrate an implementation of a wedge shaped light guide 100 that can be used to collect light. The wedge shaped light guide 100 includes a first side 101, a second side 102 and a third side 103. The first side 101 and the third side 103 subtend an apex angle, a. The second side 102 can be shorter than the first side 101 and the third side 103. In various implementations, the apex angle, a can be between approximately 3 degrees and approximately 30 degrees. The length of the second side 102 can be between approximately 1 mm and approximately 10 inches. The length of the first side 101 can be between approximately 1 inch to approximately 6 feet. The third side 103 can be a portion of an inclined surface having a surface normal direction P and a surface tangent direction T. The wedge shaped light guide 100 has a refractive index n. The wedge shaped light guide 100 can include a transparent or transmissive material such as glass, plastic, polycarbonate, polyester or cyclo-olefin.

When the wedge shaped light guide is surrounded by a material (for example, air) that has a lower refractive index than the refractive index of the material “n” of the wedge shaped light guide, light 104 injected into (or received in) the second end 101 of the wedge shaped light guide, propagates through the wedge shaped light guide 100 due to total internal reflection (TIR) at successive encounters with the surface interface between the wedge shaped light guide 100 and the surrounding medium. At each reflection, the reflected light will pick up an angular shift equal to the apex angle “a.” At some point (for example, point A), the reflected light strikes the interface at an angle less than the critical angle of the material of the wedge shaped light guide 100 and the surrounding medium (for example, less than the critical angle for glass-air interface, which is about 42 degrees with respect to the normal for a glass/air interface). At this point, light refracts through the interface and exits the wedge shaped light guide 100 at an angle with respect to the surface normal. In various implementations, the angles at which light exits the wedge can be within a small angular range that is dependent on the apex angle α. For example, if the apex angle α of the wedge shaped light guide 100 is equal to about 20 degrees, the angular range that light exits the wedge shaped light guide 100 is within about 30 degrees from the surface tangent direction T or within about 60 degrees to about 90 degrees from the surface normal direction P.

Light traveling and striking the wedge shaped light guide 100 in an angular range of about 60 degrees to about 90 degrees from the surface normal direction P can be efficiently trapped and collected via TIR within the wedge shaped light guide 100 as shown in FIG. 1B. For example, rays of light 105 and 110 which strike the inclined surface including the third side 103 of the wedge shaped light guide 100 in an angular range of about 60 degrees to about 90 degrees from the surface normal direction P are trapped within the wedge shaped light guide 100 and guided through the wedge shaped light guide 100 and exits the wedges shaped light guide 100 through the second side 102. Ray of light 115 which is outside the angular range of about 60 degrees to about 90 degrees from the surface normal direction P is not trapped within the wedge shaped light guide 100 since the angle at which ray of light 115 enters the wedge shaped light guide is less than the critical angle of the material of the wedge shaped light guide 100 and the surrounding medium and is refracted out of the wedge shaped light guide 100 through the first side 101.

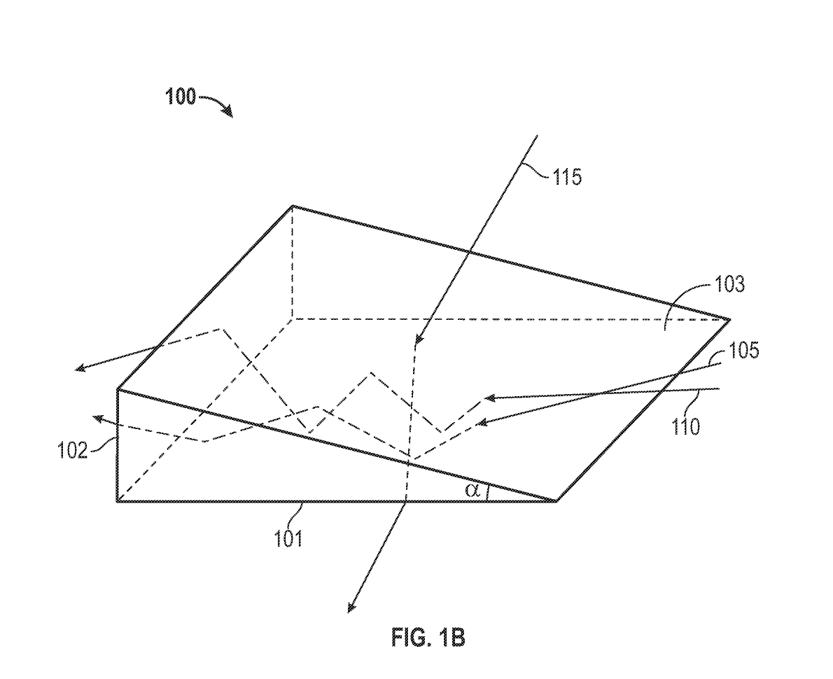

FIGS. 2A-2C illustrate implementations of a light collector 200, having microstructures, that can be used to collect light. The light collector 200 includes an array of microlenses 205 disposed on a first side (side 1 in FIG. 2A) of the light collector 200 and an array of turning features 207 disposed on a second side (side 2 in FIG. 2) of the light collector 200. Each microlens in the array of microlenses 205 can have a parabolic or an elliptical cross-section. Each microlens in the array of microlenses 205 can have a width between approximately 10 μm and approximately 50 mm. The distance between adjacent microlenses (pitch) in the array of microlenses 205 can be between approximately 1 mm and approximately 1 cm. In some implementations, microlenses that are adjacent to each other can physically contact each other such that the distance between adjacent microlenses is zero. In such implementations, the pitch can be approximately equal to the diameter of the microlens if the microlens is spherical.

In various implementations, the array of turning features 207 can include prismatic features. The prismatic features can include elongated grooves disposed on the second side of the microstructured light collector 200 which may be filled with an optically transmissive material. The prismatic features can include a variety of shapes. For example, the prismatic features can be linear v-grooves, curvilinear grooves or other non-linear shapes. In various implementations, the array of turning features 207 can include surface or volume diffractive features. The distance between adjacent turning features (which is also referred to as pitch) may be between approximately 1 mm and approximately 1 cm. In some implementations, the array of turning features 207 can include holograms.

Light (for example, rays 215 and 220) incident onto the first side of the microstructured light collector 200 within an angular range of about ±20 degrees with respect to a normal to the surface of microstructured light collector 200 is focused by the array of microlenses 205 onto the array of turning features 207. The array of turning features 207 is configured to turn the focused light such that it is trapped in the microstructured light collector 200. In some implementations, the array of turning features 207 can be arranged such that each turning feature in the array of turning features 207 is below a corresponding microlens from the array of microlenses 205. In some implementations, the array of turning features 207 can be arranged such that each turning feature in the array of turning features 207 is offset by approximately 1 mm to approximately 1 cm with respect to the optical axis of a corresponding microlens in the array of microlenses 205, the offset indicated by the reference numeral 215 in FIG. 2B. Offsetting the turning features 207 with respect to the microlenses 205 may be advantageous in collecting light incident at non-normal angles. The density of turning features (for example, number of turning features per unit area) can be selected such that light collection efficiency is increased without adversely increasing losses due to scattering of the trapped light.

In some implementations, the array of microlenses 205 can be disposed on a top surface of a substrate 201, while the array of turning features 207 can be disposed an a bottom surface of a light guide 203. Light focused onto the array of turning features 207 can be guided through the light guide 203 towards one or more PV cells that can be disposed along one or more edges of the light guide 203. The substrate 201 and/or the light guide 203 can have a thickness between approximately 1 mm and approximately 1 cm. The substrate 201 and/or the light guide 203 can have a width between approximately 1 inch to approximately 6 feet. The substrate 201 and/or the light guide 203 can include a transmissive or transparent material such as glass, polycarbonate, polyester or cyclo-olefin. In various implementations, the substrate 201 can be separated from the light guide 203 by a gap 210. The gap 210 can be filled with air or a material having a refractive index lower than the refractive index of the material of the light guide 203. In some implementations, the layer of air or low refractive index material between the substrate 201 and the light guide 203 can increase the efficiency of light collection by reducing repeated interactions of the turned and trapped light with the array of microlenses 205, thus limiting additional loss. In some implementations, there can be no gap 210 between the substrate 201 and the light guide 203. In such implementations, to increase the efficiency of light collection, the substrate 201 and the light guide 203 can include transmissive materials having different indices of refraction such that light is guided efficiently in the light guide 203. For example, to increase the efficiency of light collection, the index of refraction of the material of the substrate 201 can be less than the index of refraction of the material of the light guide 203.

The array of microlenses 205 may be formed on the upper surface of the substrate 201 by molding, embossing, etching or other methods. In some implementations, the array of microlenses 205 may be disposed on a film which is laminated to the upper surface of the substrate 201. In various implementations, the film can include polymer such as polydimethylsiloxane (PDMS), transparent elastomers, etc. The array of turning features 207 may be formed on the bottom surface of the light guide 203 by molding, embossing, etching or other methods. In some implementations, the array of turning features 207 may be disposed on a film which is laminated to the bottom surface of the light guide 203.

In some implementations, as illustrated in FIG. 2C, the substrate 201 and the light guide 203 may be combined into a unitary light collecting/guiding structure 225 and the array of microlenses 205 is disposed on an upper surface of the unitary light collecting/guiding structure 225, while the array of turning features 207 is disposed on a bottom surface of the unitary light collecting/guiding structure 225.

To increase the angular range of light collection, wedge shaped light collector 100 and microstructured light collector 200 may be combined as further described below.

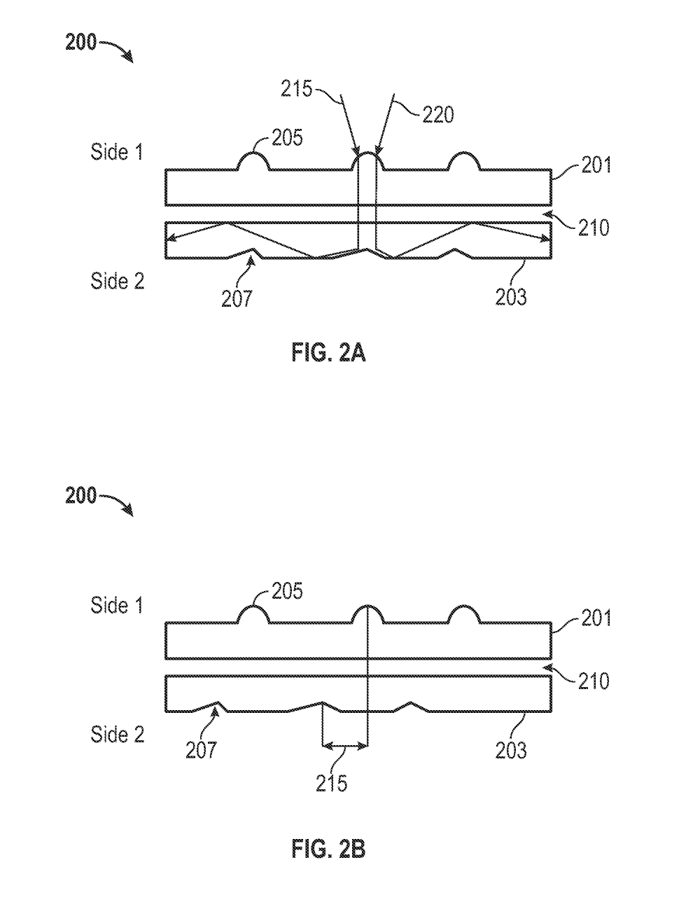

FIGS. 3A-3C illustrate a cross-sectional view of an example of a hybrid light collecting structure 300 including a wedge shaped light guide 100 and a microstructured light collector 200. The wedge shaped light guide 100 and the light collector 200 can be placed side by side to each other. As shown in FIG. 3A, the light collector 200 is placed adjacent the first side 101 of the wedge shaped light guide 100, with the array of microlenses 205 facing the wedge shaped light guide 100. Furthermore, a set of PV cells 303 are placed at one end of the hybrid light collecting structure 300, near the second side 102 of the wedge shaped light guide 100. Alternatively, PV cells can be placed at both ends of the hybrid light collecting structure 300. The wedge shaped light guide 100 and the microstructured light collector 200 can be separated by a gap that can be filled with a material having a refractive index lower than the refractive index of the material of the wedge shaped light guide 100 and the microstructured light collector 200.

Still referring to FIG. 3A, light (for example, ray of light 310) that is incident on the inclined surface including side 103 of the wedge shaped light guide 100 at angles in the range of about 60 degrees to about 90 degrees with respect to a normal direction to the inclined surface including side 103 of the wedge shaped light guide 100 is collected and guided by the wedge shaped light guide 100 towards one or more PV cells 303 disposed adjacent the second side 102 of the wedge shaped light guide 100. Light (for example, ray of light 315) that is incident on the inclined surface including side 103 of the wedge shaped light guide 100 at angles in the range of about 0 degrees to about 30 degrees with respect to a normal direction to the inclined surface including side 103 of the wedge shaped light guide 100 is refracted out of the wedge shaped light guide 100. Such light is then incident on the microstructured light collector 200 as shown in FIG. 3A. The microstructured light collector 200 collects and guides the incident light towards the one or more PV cells 303. The hybrid light collecting structure 300 can advantageously collect light that would have not been collected by the wedge shaped light guide 100 alone and thus can increase the light collection efficiency. Since the wedge shaped light guide 100 can collect light incident at angles in the range of about zero (0) degrees to about 30 degrees with respect to the z-axis and the microstructured light collector 200 can collect light incident at angles in the range of about 30 degrees to about 60 degrees with respect to the z-axis, the hybrid light collecting structure 300 can efficiently collect light incident at angles in the range of about 0 degrees to about 60 degrees with respect to the z-axis.

In various implementations, the wedge shaped light guide 100 can collect and guide light that is incident at angles in the range of about 60 degrees to about 75 degrees, about 60 degrees to about 80 degrees, about 75 degrees to about 90 degrees, or about 80 degrees to about 90 degrees with respect to a normal direction to the inclined surface including side 103 of the wedge shaped light 100. In various implementations, the wedge shaped light guide 100 can collect and guide light that is incident at angles in the range of about 40 degrees to about 65 degrees with respect to a normal direction to the inclined surface including side 103 of the wedge shaped light 100. In various implementations, the wedge shaped light guide 100 can be configured to collect and guide light incident at angles outside the range of angles provided above. In various implementations, the light collector 200 can collect and guide light that is incident at angles in the range of about 0 degrees to about 65 degrees, about 5 degrees to about 30 degrees, about 5 degrees to about 45 degrees, or about 20 degrees to about 50 degrees with respect to a normal direction to the inclined surface including side 103 of the wedge shaped light 100. In various implementations, the light collector 200 can collect and guide light that is incident at angles in the range of about 45 degrees to about 60 degrees with respect to a normal direction to the inclined surface including side 103 of the wedge shaped light 100. In various implementations, the light collector 200 can be configured to collect and guide light incident at angles outside the range of angles provided above.

A duplicate hybrid light collecting structure including a second wedge shaped light collector 100a (FIGS. 3B and 3C) configured to collect light incident at angles in the range of about 0 degrees to about −30 degrees with respect to the z-axis and a second light collector 200a configured to collect light in the range of about −30 degrees to about −60 degrees with respect to the z-axis can be disposed adjacent the bottom surface of the light collector 200. Such an arrangement can further increase the angular range over which incident light is collected.

The PV cells 303 can convert the captured light into electrical power. In various implementations, the PV cells 303 can include solar cells. The PV cells 303 can include a single or a multiple layer p-n junction and may be formed of silicon, amorphous silicon or other semiconductor materials such as Cadmium telluride. In some implementations, PV cells 303 can include photo-electrochemical cells. Polymer or nanotechnology may be used to fabricate the PV cells 303. PV cells 303 can include multispectrum layers, each multispectrum layer having a thickness between approximately 1 μm to approximately 250 μm. The multispectrum layers can further include nanocrystals dispersed in polymers. Several multispectrum layers can be stacked to increase efficiency of the PV cells 303.

As discussed above, the wedge shaped light guides 100 and 100a and the light collectors 200 and 200a can include optically transmissive or transparent material such as glass, plastic, acrylic, polycarbonate, polyester or cyclo-olefin polymer. In various implementations, the wedge shaped light guides 100 and 100a and the light collectors 200 and 200a can include optically transmissive material that is transparent to radiation at one or more wavelengths that the PV cell 303 is sensitive to. For example, in some implementations, the wedge shaped light guides 100 and 100a and the light collectors 200 and 200a may be optically transmissive to wavelengths in the visible and near infra-red region. In other implementations, the wedge shaped light guides 100 and 100a and the light collectors 200 and 200a may be transparent to wavelengths in the ultra-violet or infra-red regions. In various implementations, the hybrid wedge shaped light guides 100 and 100a and the light collectors 200 and 200a may have wavelength filtering properties to filter out ultra-violet or infra-red. The wavelength filtering properties may be provided to the hybrid wedge shaped light guides 100 and 100a and the light collectors 200 and 200a by including a dielectric film or any other film configured to filter out the ultra-violet or infra-red. Ultra-violet or infra-red radiation may be filtered out by absorbing, reflecting or transmitting the ultra-violet or infra-red.

In various implementations, the individual length and width of the wedge shaped light guides 100 and 100a and the light collectors 200 and 200a may be greater than the individual thickness of the wedge shaped light guides 100 and 100a and the light collectors 200 and 200a. For example, the individual thickness of the wedge shaped light guides 100 and 100a and the light collectors 200 and 200a may vary from approximately 1 mm to approximately 10 cm. The individual length and width of the wedge shaped light guides 100 and 100a and the light collectors 200 and 200a may be such that the individual area of the wedge shaped light guides 100 and 100a and the microstructured light collectors 200 and 200a varies from approximately 0.01 cm² to approximately 50,000 cm². Dimensions outside these ranges, however are possible.

The implementations of the hybrid light collecting structure 300 illustrated in FIGS. 3A and 3B can be configured to collect ambient light incident on numerous surfaces, in other words, over a volume as illustrated in FIG. 3C. The implementation illustrated in FIG. 3C can reduce the need for tracking the movement or location of the light source, e.g., the sun, since the projected collection area is relatively independent of the position of the sun. The implementation illustrated in FIG. 3C can collect light over a wide range of incident angles and thus can be advantageous in non-tracking light collecting systems. In the implementation illustrated in FIG. 3C, the wedge shaped light guides 100 and 100a can collect light when the sun is overhead, for example at noon, when light is incident at more normal angles. The light collectors 200 and 200a can collect light when the sun is low over the horizon, for example in the morning and evening, when light is incident at more grazing angles. The collected light is directed towards one or more PV cells 303. In the implementation illustrated in FIG. 3C, the volume over which light is collected increases by increasing the height of the light collecting structure. Since the volume over which light is collected increases more rapidly than the surface area of the one or more PV cells 303, this structure can increase the photovoltaic conversion efficiency without increasing the area of the one or more PV cells 303. The implementation of the hybrid light collecting structure 300 as illustrated in FIGS. 3A-3C can be configured as a portion of a facade of a building.

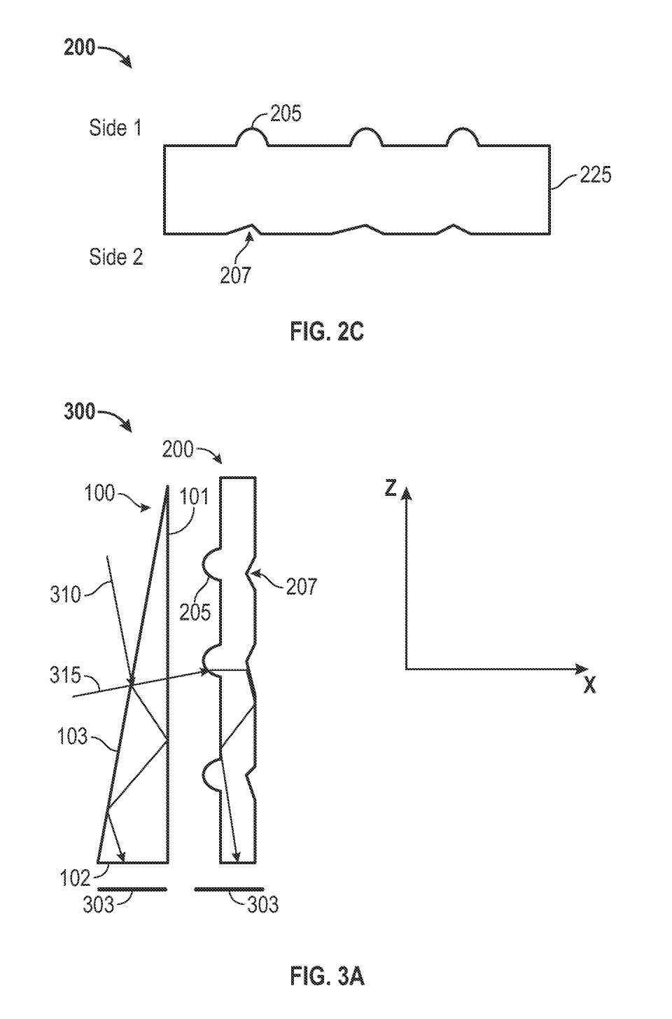

FIG. 4 illustrates a cross-sectional side view of and implementation of a hybrid light collecting structure 400 that can be disposed on windows of buildings. The hybrid light collecting structure 400 illustrated in FIG. 4A includes a wedge shaped light guide 100 and a microstructured light collector 200. As discussed above, the microstructured light collector 200 includes an array of microlenses 205 disposed on an upper surface of a substrate 201. The substrate 201 may be wedge shaped and includes a first side 230, a second side 235 and a third side 240. The third side 240 defines an edge of an inclined surface. The third side 240 and the first side 230 of the substrate 201 can subtend an apex angle β. The microlenses 205 can be disposed such that the lenticular portions of the microlenses 205 face the third side 103 of the wedge shaped light guide 100, as shown in FIG. 4.

In the implementation illustrated in FIG. 4, the wedge shaped substrate 201 is arranged such that the inclined surface defined by the third side 240 faces the inclined surface defined by the third side 103 of the wedge shaped light guide 100. Since the hybrid light collecting structure 400 is configured to be disposed on windows or for use as a window, arranging the wedge shaped light guide 100 and the microstructured light collector 200 such that the inclined surfaces face each other can advantageously reduce distortion of objects that are viewed through the hybrid light collecting structure 400.

Light (for example, ray 410) that is incident on the wedge shaped light guide 100 at angles in the range of about 0 degrees to about 30 degrees with respect to the z-axis is collected by the wedge shaped light guide 100 and guided towards one or more PV cells 303a disposed on a side of the hybrid light collecting structure 400 adjacent the second side 102 of the wedge shaped light guide 100. Light (for example, rays 415 and 420) that is incident on the wedge shaped light guide 100 at angles in the range of approximately 30 degrees to about 90 degrees with respect to the z-axis is focused onto the array of turning features 207 by the array of microlenses 205 disposed in the wedge shaped substrate 201 and guided within the light guide 203 towards one or more PV cells 303b that are disposed on a side of the hybrid light collecting structure 400 that is opposite to the side on which the one or more PV cells are disposed. Since light strikes the windows at angles of 0 degrees to 90 degrees depending on various factors, such as, for example, the time of the day and the position of the sun, the hybrid light collecting structure 400 can efficiently collect ambient solar flux throughout the day. For example, the wedge shaped light guide 100 can efficiently collect and guide light that is incident at grazing angles (for example, in the morning or evening), while the wedge shaped microstructured light collector 200 can efficiently collect light that is incident at more normal angles (for example in the afternoon).

In various implementations, the thickness of the hybrid light collecting structure 400 that is configured for use in windows may be less than 8 inches. In various implementations, the apex angles α and β of the wedge shaped light guide 100 and the wedge shaped substrate 201 can be between about 3 degrees and 30 degrees.

In various implementations, the hybrid light collecting structure 300 or 400 can include thin film having reflecting, diffracting or scattering features that can reflect, diffract or scatter portion of the incident light such that the reflected, scattered or diffracted light is guided in the wedge shaped light guide 100 or the microstructured light collector 200. In various implementations, reflective thin films are disposed below the microstructured light collector 200 such that incident light passes through the wedge shaped light guide 100 and the microstructured light collector 200 before being incident on the reflective thin film. Thin films that are partially reflective and partially transmissive can be disposed between the wedge shaped light guide 100 and the microstructured light collector 200. The thin films can increase the light collection efficiency.

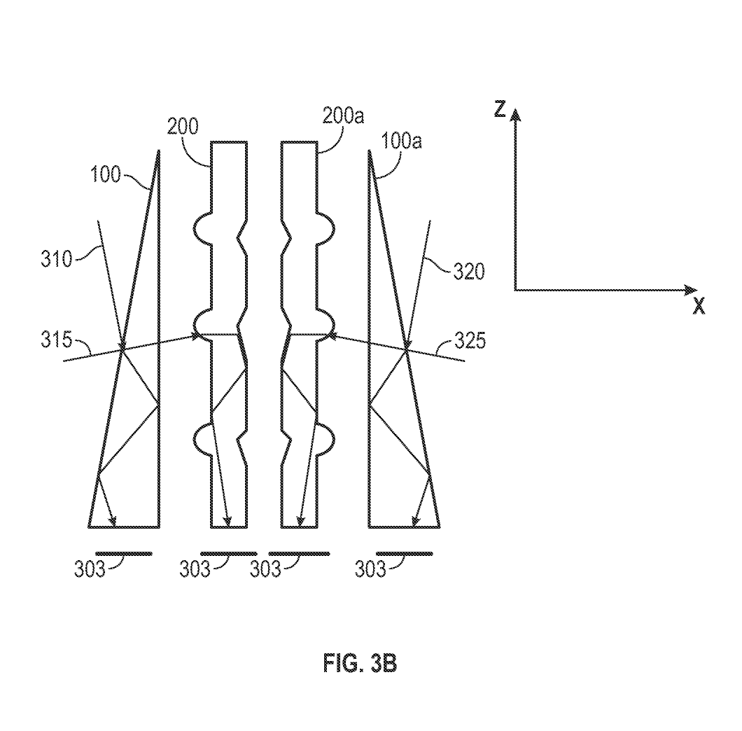

Various implementations of hybrid light collecting structures described herein to efficiently collect, concentrate and direct light to a PV cell and thus can be used to provide solar cells that have increased photovoltaic conversion efficiency and can be relatively inexpensive, thin and lightweight compared to some conventional solar cells. The solar cells including hybrid light collecting structures coupled to one or more PV cells may be arranged to form panels of solar cells. Such panels of solar cells can be used in a variety of applications. For example, as described above, implementations of hybrid light collecting structures coupled to one or more PV cells can be configured as building-integrated photovoltaic products such as, for example, windows, roofs, skylights, facades, etc. to generate electrical power. For example, FIG. 5 illustrates a hybrid light collecting structure 504 coupled to a set of PV cells 508 that can be integrated with a building 500. For example, the hybrid light collecting structure 504 coupled to a plurality of PV cells 508 can be disposed on roofs and doors or configured as a skylight, windows or a portion of facades of buildings. Some examples of the hybrid light collecting structure 504 include the hybrid light collectors 300 and 400 described above. In various implementations, the hybrid light collecting structure 504 can be provided with optical elements or coating that reduce glare. In various implementations, the hybrid light collecting structure 504 can be colorized (for example red or brown) for aesthetic purposes. In some implementations, the hybrid light collecting structure 504 may be tinted or colorized to reduce the amount of light transmitted. In various implementations, the hybrid light collecting structure 504 may have wavelength filtering properties to filter out ultra-violet or infra-red radiation as discussed above.

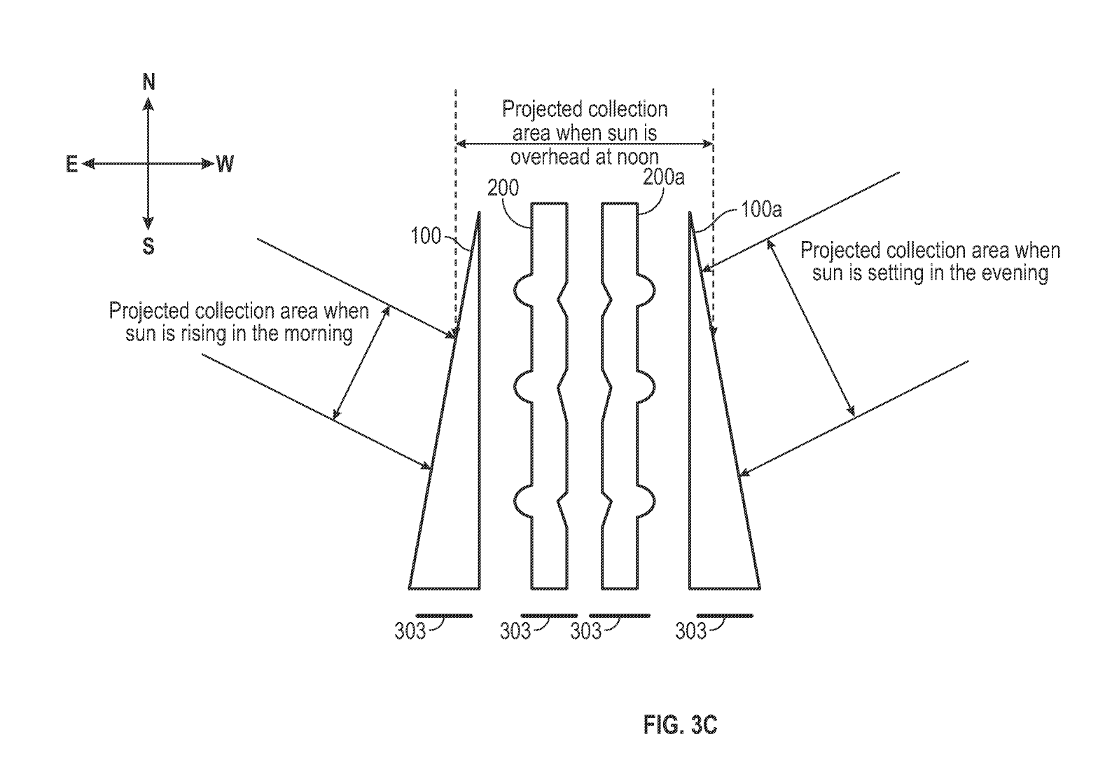

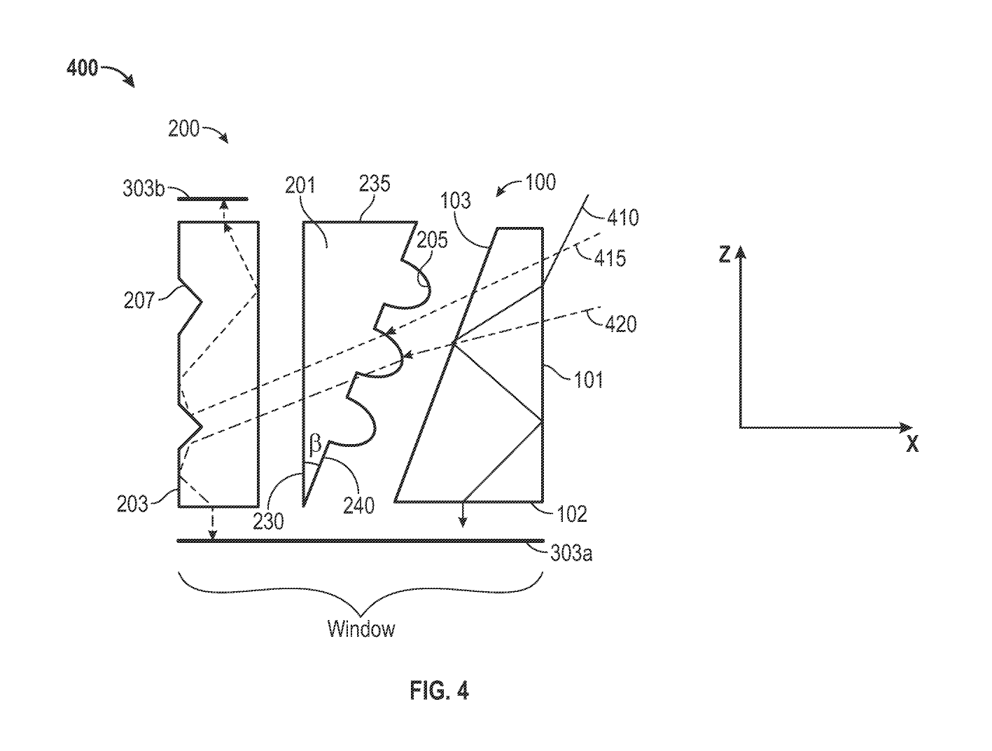

In other applications, implementations of hybrid light collecting structure may be mounted on automobiles and laptops as shown in FIGS. 6 and 7 respectively to provide electrical power. FIG. 6 illustrates a hybrid light collecting structure 604 coupled to PV cells 608 disposed on an automobile 600. The hybrid light collecting structure 604 coupled to the PV cells 608 can be disposed on roof of an automobile, windows of an automobile or other exterior parts of the automobile. The hybrid light collecting structure 604 can be similar to the hybrid light collectors 300 and 400 described above. The electrical power generated by the PV cells 608 can be used for example, to recharge the battery of an automobile powered by gas, electricity or both or run electrical components as well. Panels of solar cells including hybrid light collecting structures coupled to PV cells may be mounted on various transportation vehicles, such as aircrafts, trucks, trains, bicycles, boats, etc. Panels of solar cells including hybrid light collecting structures coupled to PV cells may be mounted on satellites and spacecrafts as well.

FIG. 7 illustrates a hybrid light collecting structure 704 coupled to PV cells 708 that is attached to the housing (for example external casing) of a laptop computer 700. In various implementations, the hybrid light collecting structure for 704 can be similar to the hybrid light collectors 300 and 400 described above. The electricity generated by the PV cells can advantageously provide electrical power to the laptop in the absence of electrical connection or can be used to recharge the laptop battery.

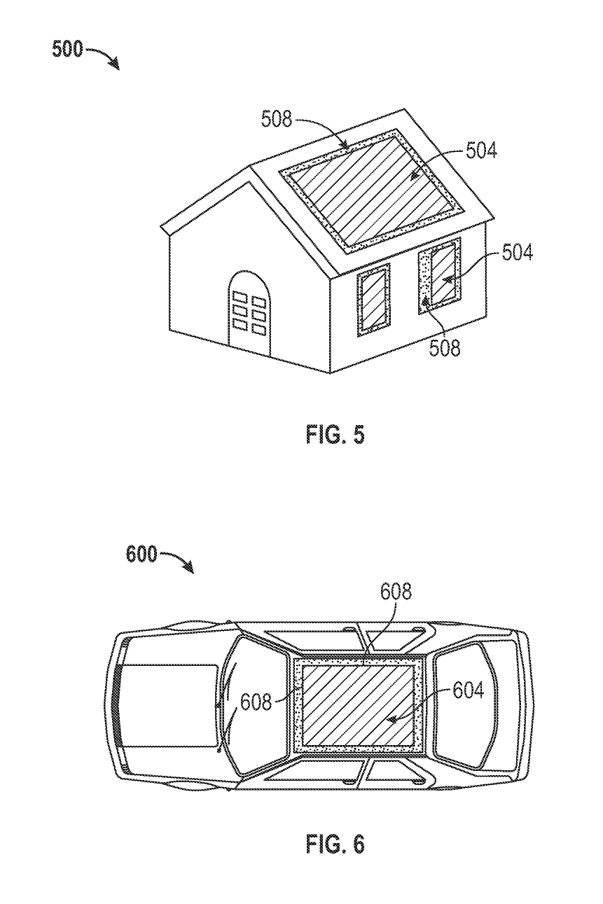

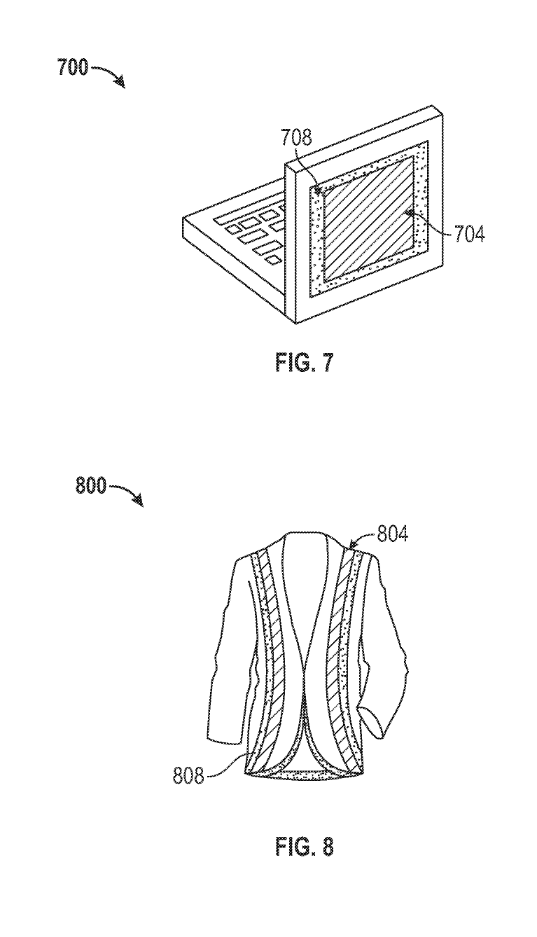

Implementations of hybrid light collecting structures coupled to PV cells may be attached to articles of clothing or shoes. For example, FIG. 8 illustrates a hybrid light collecting structure 804 coupled to PV cells 808 that is attached to an article of clothing 800 (for example, a jacket or a vest). In various implementations, the hybrid light collecting structure 804 can be similar to the hybrid light collectors 300 and 400 described above. Ambient light may be collected by the hybrid light collecting structure 804 and directed towards the PV cells 808. Electricity generated by the PV cells 808 may be used to power handheld devices such as PDAs, MP3 players, cell phone etc. Electricity generated by the PV cells 808 can also be used to light vests and jackets worn by airline ground crew, police, fire fighters and emergency workers in the dark to increase visibility. In another implementation illustrated in FIG. 9, a hybrid light collecting structure 904 coupled to PV cells 908 is disposed on a shoe 900. The hybrid light collecting structure 904 can be similar to the hybrid light collectors 300 and 400 described above.

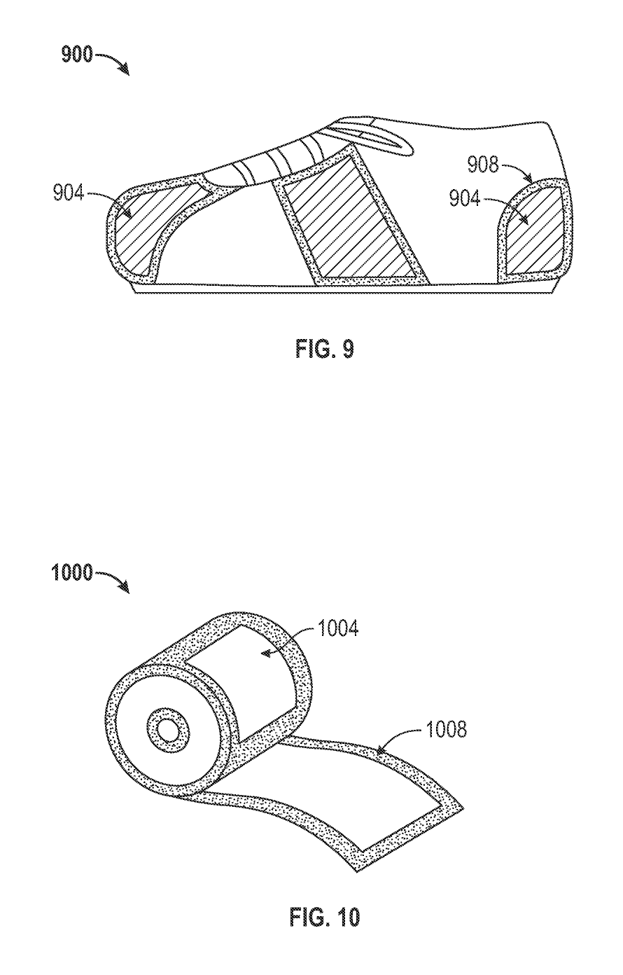

FIG. 10 illustrates a flexible sheet 1000 including a hybrid light collecting structure 1004 coupled to PV cells 1008 that are flexible to be rolled. Flexible PV cells 1008 can include flexible thin film cells and modules that are formed by depositing photovoltaic material (for example, Copper Indium Gallium Selenide (CIGS) type thin film) on a flexible substrate. Some examples of the hybrid light collecting structure include the hybrid light collectors 300 and 400 described above. The flexible sheet 1000 illustrated in FIG. 10 may be rolled and carried on camping or backpacking trips to generate electrical power outdoors and in remote locations where electrical connection is sparse. In various other implementations, hybrid light collecting structure, which are similar to the hybrid light collectors 300 and 400 described above, and optically coupled to PV cells may be attached to a wide variety of structures and products to provide electricity.

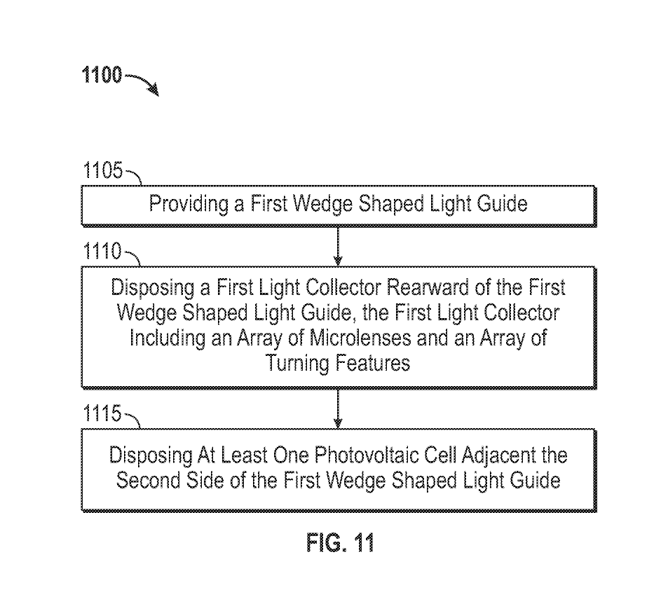

FIG. 11 is a flow chart illustrating an example of a method of manufacturing an implementation of a hybrid light collecting structure. The method 1100 includes providing a first wedge shaped light guide as illustrated in block 1105. The first wedge shaped light guide includes a first side, a second side and a third side. In various implementations, the third side can be the inclined surface of the wedge shaped light guide such that the first and the third side of the wedge shaped light guide subtend an apex angle. In various implementations, the second side is disposed opposite the apex angle. In various implementations, the second side can be shorter in length than the first side and the third side. In various implementations, the first wedge shaped light guide is configured to collect and guide light incident in a first angular range on the inclined surface of the wedge shaped light guide. In various implementations, the first angular range can be between about 60 degrees to about 90 degrees with respect to a normal to the inclined surface of the wedge shaped light guide. In various implementations, the apex angle can be between about 3 degrees and 30 degrees.

The method 1100 further includes disposing a first light collector rearward of the first wedge shaped light guide, the first light collector including an array of microlenses and an array of turning features as shown in block 1110. The first light collector is configured to collect light that exits the first wedge shaped light guide and is incident on the first light collector in a second angular range different from the first angular range. In various implementations, the second angular range can be between about 0 degrees and about 60 degrees with respect to a normal to the inclined surface first wedge shaped light guide. The array of microlenses can be disposed on a first side of the first light collector that is proximal to the wedge shaped light guide. The array of turning features can be disposed on a second side of the first light collector that is opposite the first side. In various implementations, the array of microlenses and the array of turning features can be provided by methods such as, for example, embossing, etching, lithography, etc. In various implementations, the array of microlenses and the array of turning features can be provided on one or more films which may be adhered to surfaces of the first light collector by a pressure sensitive adhesive or may be laminated to the surfaces of the first light collector

The method 1100 further includes disposing at least one PV cell adjacent the second side of the first wedge shaped light guide as shown in block 1115. The PV cell configured to receive light incident through the inclined surface of the first wedge shaped light guide and trapped by total internal reflection within the first wedge shaped light guide and the first light collector.

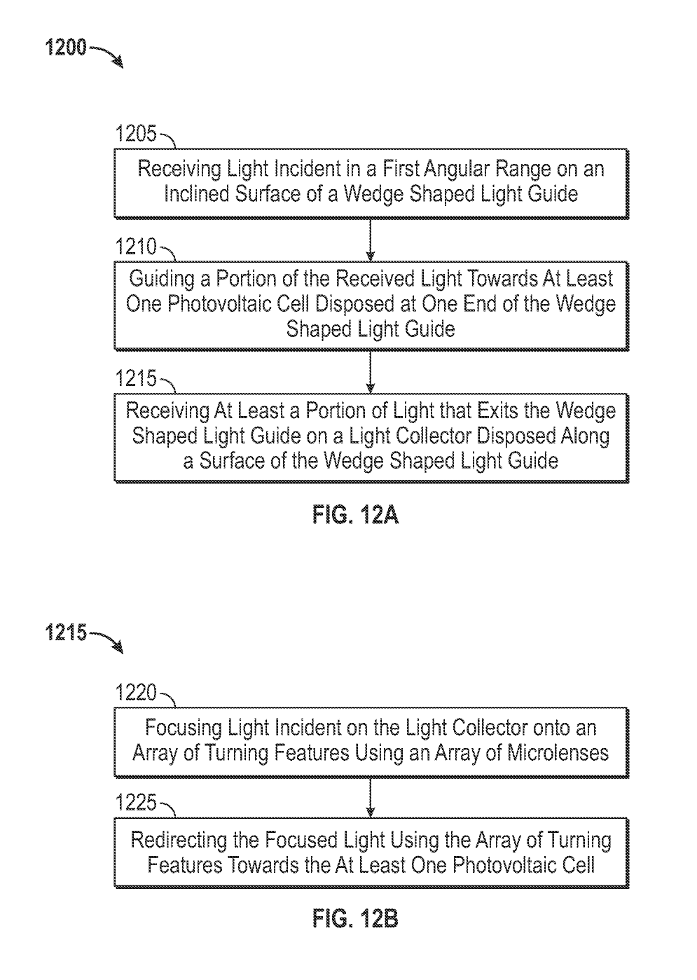

FIGS. 12A and 12B are flow charts illustrating an example of a method of directing light towards a PV cell using an implementation of a hybrid light collecting structure. The method 1200 includes receiving light incident in a first angular range on an inclined surface of a wedge shaped light guide, as shown in block 1205. In various implementations, the first angular range can be between about 60 degrees and about 90 degrees with respect to a normal to the inclined surface of the wedge shaped light guide.

The method 1200 further includes guiding a portion of the received light towards at least one PV cell disposed at one end of the wedge shaped light guide, as shown in block 1210. The method 1200 further includes receiving at least a portion of light that exits the wedge shaped light guide on a light collector disposed along a surface of the wedge shaped light guide, as shown in block 1215. The light collector is configured to collect and guide light by focusing light incident on the light collector onto an array of turning features using an array of microlenses, as shown in block 1220. The focused light is redirected using the array of turning features towards the at least one PV cell, as shown in block 1225. The array of microlenses is disposed on a first side of the light collector that is positioned proximal to the wedge shaped light guide, and the array of turning features is disposed on a second side of the light collector opposite the first side. In various implementations, the light collector can be configured to collect and guide light that is incident in an angular range that is between about 0 degrees and about 60 degrees with respect to the normal to the inclined surface of the wedge shaped light guide.

Hybrid light collecting structures, which are similar to the hybrid light collectors 300 and 400 described above, and optically coupled to PV cells may have an added advantage of being modular. For example, depending on the design, the PV cells may be configured to be removably attached to the hybrid light collecting structures. Thus existing PV cells can be replaced periodically with newer and more efficient PV cells without having to replace the entire system. This ability to replace PV cells may reduce the cost of maintenance and upgrades substantially.

A wide variety of other variations are also possible. Films, layers, components, and/or elements may be added, removed, or rearranged. Additionally, processing operations may be added, removed, or reordered. Also, although the terms film and layer have been used herein, such terms as used herein include film stacks and multilayers. Such film stacks and multilayers may be adhered to other structures using adhesive or may be formed on other structures using deposition or in other manners.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus, comprising:
a wedge-shaped first light guide configured to guide light incident on a light receiving surface of the first light guide within a first angular range, the first light guide including
a first side;
a second side;
a third side including the light receiving surface, the first and third side subtending a first apex angle and a portion of the third side defining a surface plane having a normal direction P, wherein the second side is disposed opposite the first apex angle and the second side is shorter in length than the first side and the third side; and
a first light collector positioned adjacent to the first side of the first light guide to receive light that exits the first side of the first light guide, the first light collector including
microlenses disposed on a first side of the first light collector proximate to the first side of the first light guide, each of the microlenses having an optical axis, wherein the microlenses are configured to propagate incident light received at a second angular range different from the first angular range into the first light collector; and
turning features disposed on a second side of the first light collector opposite the microlenses and angled to reflect light received through the microlenses towards an illumination surface of the first light collector disposed proximate to the second side of the light guide; and
at least one photovoltaic cell disposed adjacent to the second side of the first light guide and to the illumination surface.

2. The apparatus of claim 1, further comprising a wedge-shaped second light guide and a second light collector, the second light collector disposed adjacent to the first light collector such that a side having turning features of the second light collector is disposed proximate to the side of the first light collector having turning features, and the wedge-shaped second light guide having a first side, a second side, and a third side including a light receiving surface, the first and third side subtending a second apex angle and the second side disposed opposite the second apex angle and the second side is shorter in length than the first side and the third side, is disposed such that the first side of the second light guide is adjacent to the second light collector on a side of the second light collector opposite the first light collector.

3. The apparatus of claim 2, wherein the second apex angle is between about 3 and 30 degrees.

4. The apparatus of claim 2, wherein the apparatus is configured as a portion of a facade of a building

5. The apparatus of claim 1, wherein the first apex angle is between about 3 and 30 degrees.

6. The apparatus of claim 1, wherein the first angular range is between about 60 degrees and 90 degrees from the direction of the surface normal P.

7. The apparatus of claim 1, wherein the second angular range is between about 0 degrees and 60 degrees from the direction of surface normal P.

8. The apparatus of claim 1, wherein the alignment of each of the turning features is offset with respect to the optical axis of each of the microlenses by a distance which is between approximately 1 mm and approximately 1 cm.

9. The apparatus of claim 1, wherein light incident on the first light collector is focused by the microlenses onto the array of turning features.

10. The apparatus of claim 9, wherein the turning features are configured to redirect the light towards the at least one photovoltaic cell.

11. The apparatus of claim 1, wherein the first light collector includes
a substrate having a first surface and a second surface rearward of the first surface, the microlenses disposed on the first surface of the substrate; and
a light guide layer having a forward and a rearward surface, the forward surface of the light guide disposed proximal to the second surface of the substrate and configured to receive incident light, the turning features disposed on the rearward surface of the light guide layer.

12. The apparatus of claim 11, including a layer of material disposed between the light guide layer and the substrate.

13. The apparatus of claim 12, wherein the layer of material has a refractive index characteristic lower than the refractive index of the light guide and the refractive index of the substrate.

14. The apparatus of claim 1, wherein the turning features includes prismatic features.

15. The apparatus of claim 1, wherein the apparatus is attached to a window of a building.

16. The apparatus of claim 1, wherein the apparatus is configured as a window of a building.

17. The apparatus of claim 1, wherein the apparatus is configured as a skylight of a building.

18. An apparatus, comprising:
a wedge-shaped first means for guiding light that is incident on a light receiving surface of the first light guiding means within a first angular range towards at least one photovoltaic cell disposed adjacent to a surface of the first light guiding means; and
a second means for guiding light, received at a second angular range different from the first angular range, towards at least one photovoltaic cell disposed adjacent to a surface of the second light guiding means, the second light guiding means positioned adjacent to a first side of the first light guiding means to receive light that exits the first side of the first light guiding means.

19. The apparatus of claim 18, wherein the first light guiding means includes a first light guide including
a first side;
a second side; and
a third side including a light receiving surface, the first and third side subtending a first apex angle of between approximately 3 and approximately 30 degrees and a portion of the third side defining a surface plane having a normal direction P, wherein the second side is disposed opposite the first apex angle and the second side is shorter in length than the first side and the third side.

20. The apparatus of claim 18, wherein the second light guiding means includes
microlenses disposed on a side of the second light guiding means proximate to a first side of the first light guiding means; and
turning features disposed on a side of the second light guiding means opposite the microlenses, the light turning features having at least one angled surface configured to reflect light passing through the microlenses towards the at least one photovoltaic cell.

21. The apparatus of claim 18, further comprising
a wedge-shaped third means for guiding light, that is incident on a light receiving surface of the third light guiding means within a first angular range, towards at least one photovoltaic cell disposed adjacent to a surface of the third light guiding means; and
a fourth means for guiding light, received at a second angular range different from the first angular range, towards at least one photovoltaic cell disposed adjacent to a surface of the fourth light guiding means, the fourth light guiding means positioned adjacent to a first side of the third light guiding means to receive light that exits the first side of the third light guiding means,
wherein the fourth light guiding means is disposed adjacent to the second light guiding means.

22. A method of manufacturing an apparatus, the method comprising:
providing a first wedge shaped light guide configured to collect and guide light in a first angular range, the first wedge shaped light guide including a first side, a second side and a third side, the third side including the light receiving surface, the first and third side subtending a first apex angle, wherein the second side is disposed opposite the first apex angle and the second side is shorter in length than the first side and the third side;
disposing a first light collector rearward of the first wedge shaped light guide, the first light collector including an array of microlenses and an array of turning features, the first light collector configured to collect light that exits the first wedge shaped light guide and is incident on the first light collector in a second angular range different from the first angular range; and
disposing at least one photovoltaic cell adjacent the second side of the first wedge shaped light guide, the photovoltaic cell configured to receive light incident through the inclined surface of the first wedge shaped light guide and trapped by total internal reflection within the first wedge shaped light guide and the first light collector.

23. The method of claim 22, wherein the array of microlenses are formed by a process including at least one of: embossing, etching, imprinting and lithography.

24. The method of claim 22, wherein the array of turning features are formed by a process including at least one of: embossing, etching, imprinting and lithography.

25. The method of claim 22, wherein the array of microlenses is provided on a first side of the first light collector that is proximal to the wedge shaped light guide.

26. The method of claim 25, wherein the array of microlenses is provided on a film that is disposed on the first side of the first light collector.

27. The method of claim 22, wherein the array of turning features is provided on a second side of the first light collector that is opposite the first side.

28. The method of claim 27, wherein the array of turning features is provided on a film that is disposed on the second side of the first light collector.

29. A method of directing light towards a photovoltaic cell, the method comprising:
receiving light incident in a first angular range on an inclined surface of a wedge shaped light guide; and
guiding a portion of the received light towards at least one photovoltaic cell disposed at one end of the wedge shaped light guide;
receiving at least a portion of light that exits the wedge shaped light guide on a light collector disposed along a surface of the wedge shaped light guide, wherein the light collector is configured to collect and guide light by
focusing light incident on the light collector onto an array of turning features using an array of microlenses, the array of microlenses being disposed on a first side of the light collector that is positioned proximal to the wedge shaped light guide, and wherein the array of turning features is disposed on a second side of the light collector opposite the first side, and
redirecting the focused light using the array of turning features towards the at least one photovoltaic cell.

30. The method of claim 29, wherein the first angular range is between about 60 degrees and about 90 degrees with respect to a normal to the inclined surface.

31. The method of claim 29, wherein the light collector is configured to collect and guide light that is incident in a second angular range between about 0 degrees and about 60 degrees with respect to a normal to the inclined surface.
